(19) United States
(12) Patent Application Publication
(10) Pub. No.: US 2014/0353014 A1
(43) Pub. Date: Dec. 4, 2014

(54) COMBINED CIRCUIT BOARD AND METHOD OF MANUFACTURING THE SAME

(71) Applicant: MUTUAL-TEK INDUSTRIES CO., LTD., New Taipei City (TW)

(72) Inventor: Wen-Chin Lai, New Taipei City (TW)

(73) Assignee: MUTUAL-TEK INDUSTRIES CO., LTD., New Taipei City (TW)

(21) Appl. No.: 14/295,121

(22) Filed: Jun. 3, 2014

(30) Foreign Application Priority Data
Jun. 3, 2013 (TW) 102119669

(51) Int. Cl. H05K 1/11; H05K 3/46; H05K 3/40

(52) U.S. Cl. CPC H05K 1/115; H05K 3/4038; H05K 3/4679
USPC 174/254; 29/852

(57) ABSTRACT

A combined circuit board including a flexible circuit board (FCB), a rigid circuit board (RCB), and first and second conductive vias (CVs) is provided. The FCB includes a flexible dielectric layer (DL) and a circuit layer (CL) disposed thereon. The RCB includes a rigid DL and a CL including a main circuit (MC) and an out connection interface circuit (OCIC). The rigid DL is disposed on the FCB and includes first and second rigid dielectric portions (RDPs) apart from each other by a distance such that part of the FCB is exposed outside. The MC and the OCIC are disposed on the first and the second RDPs, respectively. The first CV disposed in the second RDP electrically connects a contact of the OCIC and the CL of the FCB. The second CV disposed in the first RDP electrically connects the MC and the CL of the FCB.

### CROSS REFERENCE TO RELATED APPLICATIONS

This application is based on and claims the benefit of priority from Taiwan Patent Application 102119669 filed on Jun. 3, 2013, which is incorporated herein by reference and assigned to the assignee hereof.

### FIELD OF THE INVENTION

The present invention is related to a circuit board and a method of manufacturing the same and in particular, to a combined circuit board and a method of manufacturing the same.

### DESCRIPTION OF THE PRIOR ART

In general, a conventional circuit board for carrying and electrically connecting a plurality of electronic components substantially comprises circuit layers and dielectric layers that are stacked alternately. Each of the circuit layers are defined and formed by performing a patterning process on a conductive layer. Each of the dielectric layers is disposed between adjacent ones of the circuit layers in order to space apart the adjacent circuit layers. In addition, each of the stacked circuit layers may be electrically connected to another by a conductive via. Furthermore, various electronic components (such as active components or passive components) can be disposed on a surface of the circuit board, and electrical signal propagation is achieved by means of an internal circuit of the circuit board.

Due to miniaturization of any of electronic products, the application of circuit boards rapidly increases; for example, circuit boards can be applied in clam type mobile phones and notebook computers. Accordingly, the development of combing a rigid circuit board and a flexible circuit board to form a combined circuit board is required.

FIG. 1 is a schematically illustrated cross-sectional view of a conventional combined circuit board. Referring to FIG. 1, the conventional combined circuit board 100 comprises a flexible circuit board 110, a rigid circuit board 120, a rigid dielectric layer 130, a plurality of conductive vias 140, and a reinforcing plate 150. The flexible circuit board 110 comprises a flexible dielectric layer 112 and a circuit layer 114. The circuit layer 114 is disposed on a surface 112a of the flexible dielectric layer 112. The circuit layer 114 comprises a plurality of golden finger contacts 114a and only one contact 114a is schematically shown in FIG. 1. The reinforcing plate 150 is disposed on another surface 112b of the flexible dielectric layer 112 and corresponds in position to the golden finger contacts 114a.

The rigid circuit board 120 comprises a rigid dielectric layer 122 and a circuit layer 124. The rigid dielectric layer 122 is disposed on the surface 112a of the flexible dielectric layer 112 and the circuit layer 124 is disposed on the rigid dielectric layer 122 such that the rigid dielectric layer 122 is located between the flexible circuit board 110 and the circuit layer 124. The circuit layer 124 comprises a plurality of pads 124a. The conductive vias 140 are disposed in the rigid dielectric layer 122 and electrically connect the pads 124a and the golden finger contacts 114a. The rigid dielectric layer 130 is disposed on the surface 112b of the flexible dielectric layer 112 and corresponds in position to the rigid dielectric layer 122. Moreover, a chip (not shown) may be disposed on the rigid dielectric layer 122 and electrically connected to the pads 124a by means of wire bonding technology so as to be electrically connected to the golden finger contacts 114a.

The combined circuit board 100 has a thickness T1 in the vicinity of the golden finger contacts 114a and the thickness T1 can be 0.2 mm to meet the current industrial requirements. However, based on the limitation caused by the physical properties of the materials which are usually selected by the current industry for the rigid dielectric layers 122 and 130, a maximum thickness T2 of the combined circuit board 100, i.e., the thickness in the vicinity of the rigid dielectric layers 122 and 130, must be at least 0.3 mm. Hence, the conventional combined circuit board 100 cannot be further thinned.

Moreover, the process of manufacturing the conventional combined circuit board 100 is complicated. During the manufacturing process of the combined circuit board 100, the golden finger contacts 114a are preformed on the surface 112a of the flexible dielectric layer 112, and thus the flexible circuit board 110 is finished in advance. Afterward, the manufacturing process involves laminating a rigid substrate, the flexible circuit board 110 and the rigid dielectric layer 130, wherein the rigid substrate comprises the rigid dielectric layer 122 and a conductive layer disposed on the rigid dielectric layer 122 and usually a copper layer on a whole surface of the rigid dielectric layer 122. Afterward, the manufacturing process involves patterning the conductive layer to form the circuit layer 124 and performing drilling and electroplating steps to form the conductive vias 140. In doing so, the production of the conventional combined circuit board 100 is finalized. However, in the steps of lamination, patterning the conductive layer, and forming the conductive vias 140, the golden finger contacts 114a must be properly protected to be prevented from being damaged in the aforesaid steps. Moreover, when the golden finger contacts 114a are being formed, it is necessary to dispose the reinforcing plate 150 which corresponds in position to the golden finger contacts 114a to be formed. As a result, the process of manufacturing the conventional combined circuit board 100 is complicated.

### SUMMARY OF THE INVENTION

The present invention provides a combined circuit board for which the process of manufacturing is relatively simple.

The present invention provides a combined circuit board of which the thickness can be thinner.

The present invention provides a method of manufacturing a combined circuit board, wherein the manufacturing process of the combined circuit board is relatively simple.

The present invention provides a method of manufacturing a combined circuit board, wherein the combined circuit board produced has a thinner thickness.

In an embodiment of the present invention, a combined circuit board comprising a flexible circuit board, a first rigid circuit board, at least one first conductive via and at least one second conductive via is provided. The flexible circuit board comprises a flexible dielectric layer and a first circuit layer disposed on the flexible dielectric layer. The first rigid circuit board comprises a first rigid dielectric layer and a second circuit layer. The first rigid dielectric layer is disposed on the flexible circuit board and comprises a first rigid dielectric portion and a second rigid dielectric portion spaced apart from the first rigid dielectric portion by a distance to expose a portion of the flexible circuit board. The second circuit layer comprises a main circuit and an out connection interface circuit. The main circuit is disposed on the first rigid dielectric portion, and the out connection interface circuit is disposed on the second rigid dielectric portion and comprises at least one contact. The at least one first conductive via is disposed in the second rigid dielectric portion and electrically connects the at least one contact and the first circuit layer. The at least one second conductive via is disposed in the first rigid dielectric portion and electrically connects the main circuit and the first circuit layer.

In an embodiment of the present invention, the first rigid dielectric layer comprises an epoxy resin and a glass fabric which meets the style 1017 of the IPC standard.

In an embodiment of the present invention, the flexible circuit board further comprises a third circuit layer disposed on the flexible dielectric layer. The first circuit layer and the third circuit layer are disposed on two opposite sides of the flexible dielectric layer, respectively. The combined circuit board further comprises a second rigid circuit board comprising a second rigid dielectric layer and a fourth circuit layer. The second rigid dielectric layer is disposed on the flexible circuit board, and the fourth circuit layer is disposed on the second rigid dielectric layer. The second rigid dielectric layer comprises a third rigid dielectric portion and a fourth rigid dielectric portion. The third rigid dielectric portion and the fourth rigid dielectric portion correspond in position to the first rigid dielectric portion and the second rigid dielectric portion, respectively. The second rigid circuit board and the first rigid circuit board are disposed on two opposite sides of the flexible circuit board, respectively.

In an embodiment of the present invention, the first rigid dielectric layer comprises an epoxy resin and a glass fabric which meets the style 1017 of the IPC standard, and the second rigid dielectric layer comprises an epoxy resin and a glass fabric which meets the style 1017 of the IPC standard. The combined circuit board has a maximum thickness which is not larger than 0.2 mm.

In an embodiment of the present invention, the at least one contact is a golden finger contact.

In an embodiment of the present invention, a method of manufacturing a combined circuit board comprising the following steps is provided. First, a flexible circuit board comprising a flexible dielectric layer and a first circuit layer disposed on the flexible dielectric layer is provided. Next, a first rigid substrate comprising a first rigid dielectric layer and a first conductive layer disposed on the first rigid dielectric layer is provided. Next, the flexible circuit board and the first rigid substrate is laminated such that the first rigid dielectric layer is located between the first conductive layer and the flexible circuit board. Next, the first conductive layer is patterned to form a second circuit layer, wherein the first rigid dielectric layer and the second circuit layer together form a first rigid circuit board.

Next, a plurality of conductive vias in the first rigid dielectric layer are formed, wherein each of the conductive vias electrically connects the second circuit layer and the first circuit layer. Afterwards, a portion of the first rigid circuit board is removed to expose a portion of the flexible circuit board. The first rigid dielectric layer is divided into a first rigid dielectric portion and a second rigid dielectric portion spaced apart from the first rigid dielectric portion by a distance. The second circuit layer is divided into a main circuit and an out connection interface circuit. The conductive vias are divided into at least one first conductive via and at least one second conductive via. The main circuit is disposed on the first rigid dielectric portion, and the out connection interface circuit is disposed on the second rigid dielectric portion and comprises at least one contact. The at least one first conductive via is disposed in the second rigid dielectric portion and electrically connects the at least one contact and the first circuit layer. The at least one second conductive via is disposed in the first rigid dielectric portion and electrically connects the main circuit and the first circuit layer.

In an embodiment of the present invention, the first rigid dielectric layer comprises an epoxy resin and a glass fabric which meets the style 1017 of the IPC standard.

In an embodiment of the present invention, the flexible circuit board further comprises a third circuit layer disposed on the flexible dielectric layer. The first circuit layer and the third circuit layer are disposed on two opposite sides of the flexible dielectric layer, respectively. The method of manufacturing the combined circuit further comprises the following steps. A second rigid substrate comprising a second rigid dielectric layer and a second conductive layer disposed on the second rigid dielectric layer is provided. Next, the flexible circuit board and the second rigid substrate is laminated such that the second rigid dielectric layer is located between the second conductive layer and the flexible circuit board. The second rigid substrate and the first rigid substrate are disposed on two opposite sides of the flexible circuit board, respectively. Next, the second conductive layer is patterned to form a fourth circuit layer. The second rigid dielectric layer and the fourth circuit layer together form a second rigid circuit board. Next, a portion of the second rigid circuit board is removed to expose another portion of the flexible circuit board. The second rigid dielectric layer is divided into a third rigid dielectric portion and a fourth rigid dielectric portion. The third rigid dielectric portion and the fourth rigid dielectric portion correspond in position to the first rigid dielectric portion and the second rigid dielectric portion, respectively.

In an embodiment of the present invention, the first rigid dielectric layer comprises an epoxy resin and a glass fabric which meets the style 1017 of the IPC standard, and the second rigid dielectric layer comprises an epoxy resin and a glass fabric which meets the style 1017 of the IPC standard. The combined circuit board has a maximum thickness which is not larger than 0.2 mm.

In an embodiment of the present invention, the at least one contact is a golden finger contact.

During the manufacturing process of the combined circuit board of the embodiment of the present invention, the contact of the rigid circuit board comprising the out connection interface circuit is formed on the rigid dielectric layer of the rigid circuit board at the step of patterning the conductive layer. In this embodiment of the present invention, the contact is not formed yet during the laminating step and is being formed during the patterning step. Hence, compared to the conventional art, the contact of the embodiment of the present invention does not require additional protection during the two steps and the reinforcing plate is not required while the contact is being formed. Accordingly, the method of manufacturing the combined circuit board of the embodiment of the present invention is relatively simple. In addition, because the rigid dielectric layer comprises the epoxy resin and the glass fabric which meets the style 1017 of the IPC standard, compared to the conventional art, the thickness of the rigid dielectric layer can be reduced and the structural strength requirements for the rigid dielectric layer can be still meet such that the maximum thickness of the combined circuit board of this embodiment of the present invention can be effectively reduced and therefore, the combined circuit board can be thinner.

### BRIEF DESCRIPTION OF THE DRAWINGS

FIG. 1 is a schematically illustrated cross-sectional view of a conventional combined circuit board.

FIG. 2 is a schematically illustrated cross-sectional view of a combined circuit board according to an embodiment of the present invention.

FIG. 3A through FIG. 3F are schematic views illustrating a method of manufacturing a combined circuit board according to an embodiment of the present invention.

### DETAILED DESCRIPTION OF THE EMBODIMENTS

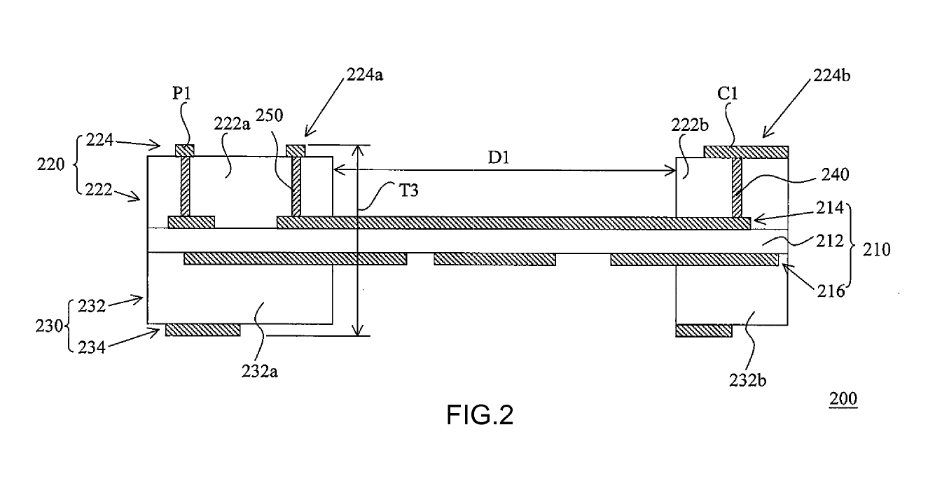

FIG. 2 is a schematically illustrated cross-sectional view of a combined circuit board according to an embodiment of the present invention. Referring to FIG. 2, the combined circuit board 200 of the embodiment comprises a flexible circuit board 210, a plurality of rigid circuit boards 220 and 230, and a plurality of conductive vias 240 and 250. The flexible circuit board 210 comprises a flexible dielectric layer 212 and two circuit layers 214 and 216. The circuit layers 214 and 216 are disposed on two opposite sides of the flexible dielectric layer 212, respectively. The flexible dielectric layer 212 comprises polyimide (PI) or epoxy resin, for example.

The rigid circuit boards 220 and 230 are disposed on two opposite sides of the flexible circuit board 210, respectively. The rigid circuit board 220 comprises a rigid dielectric layer 222 and a circuit layer 224. The rigid dielectric layer 222 is disposed on the flexible circuit board 210 and the circuit layer 224 is disposed on the rigid dielectric layer 222 such that the rigid dielectric layer 222 is disposed between the flexible circuit board 210 and the circuit layer 224. The rigid dielectric layer 222 comprises two rigid dielectric portions 222a and 222b. The rigid dielectric portion 222a and the rigid dielectric portion 222b are spaced apart from each other by a distance D1 such that a portion of the flexible circuit board 210 is exposed. The circuit layer 224 comprises a main circuit 224a and an out connection interface circuit 224b. The main circuit 224a is disposed on the rigid dielectric portion 222a. The main circuit 224a comprises at least one pad P1 and a plurality of the pads P1 are schematically shown in FIG. 2. The out connection interface circuit 224b is disposed on the rigid dielectric portion 222b. The out connection interface circuit 224b comprises a plurality of contacts C1 and only one contact C1 is schematically shown in FIG. 2. Each of the contacts C1 is a golden finger contact, for example.

A plurality of conductive vias 240 are disposed in the rigid dielectric portion 222b (only one conductive via 240 is schematically shown in FIG. 2), and each of the conductive vias 240 electrically connects one of the contacts C1 and the circuit layer 214. Moreover, the conductive vias 250 are disposed in the rigid dielectric portion 222a, and each of the conductive vias 250 electrically connects one of the pads P1 of the main circuit 224a and the circuit layer 214. In other words, each of the pads P1 of the main circuit 224a is electrically connected to one of the contacts C1 through one of the conductive vias 250, the circuit layer 214 and one of the conductive vias 240. Moreover, a chip (not shown) may be disposed on the rigid dielectric portion 222a of the rigid dielectric layer 222 and electrically connected to the pads P1 by means of wire bonding technology so as to be electrically connected to the contacts C1.

In this embodiment, the rigid circuit board 230 comprises a rigid dielectric layer 232 and a circuit layer 234. The rigid dielectric layer 232 is disposed on the flexible circuit board 210 and the circuit layer 234 is disposed on the rigid dielectric layer 232 such that the rigid dielectric layer 232 is disposed between the flexible circuit board 210 and the circuit layer 234. The rigid dielectric layer 232 comprises two rigid dielectric portions 232a and 232b. The rigid dielectric portions 232a and 232b of the rigid dielectric layer 232 correspond in position to the rigid dielectric portions 222a and 222b of the rigid dielectric layer 222, respectively.

Each of the rigid dielectric layers 222 and 232 is made of an epoxy resin and a glass fabric which meets the style 1017 of the IPC standard. That is to say, each of the rigid dielectric layers 222 and 232 comprises the epoxy resin and a plurality of fiberglass included in the glass fabric which meets the style 1017 of the IPC standard. The rigidity of each of the rigid dielectric layers 222 and 232 comprising the fiberglass and resin is relatively high. Moreover, the glass fabric which meets the style 1017 of the IPC standard has a thickness of about 10 μm and contains the fiberglass each of which has a diameter of about 4 μm. Because each of the rigid dielectric layers 222 and 232 comprises the epoxy resin and the glass fabric which meets the style 1017 of the IPC standard, compared to the conventional art, the thickness of each of the rigid dielectric layers 222 and 232 can be reduced and the structural strength requirements for them can be still meet such that the maximum thickness T3 of the combined circuit board 200 of this embodiment can be effectively reduced to 0.2 mm or even less and therefore, the combined circuit board 200 can be thinner.

In another embodiment, the rigid circuit boards 230 and the circuit layer 216 of the flexible circuit board 210 can be omitted in the combined circuit board 200, but the above mentioned is not depicted in any drawing.

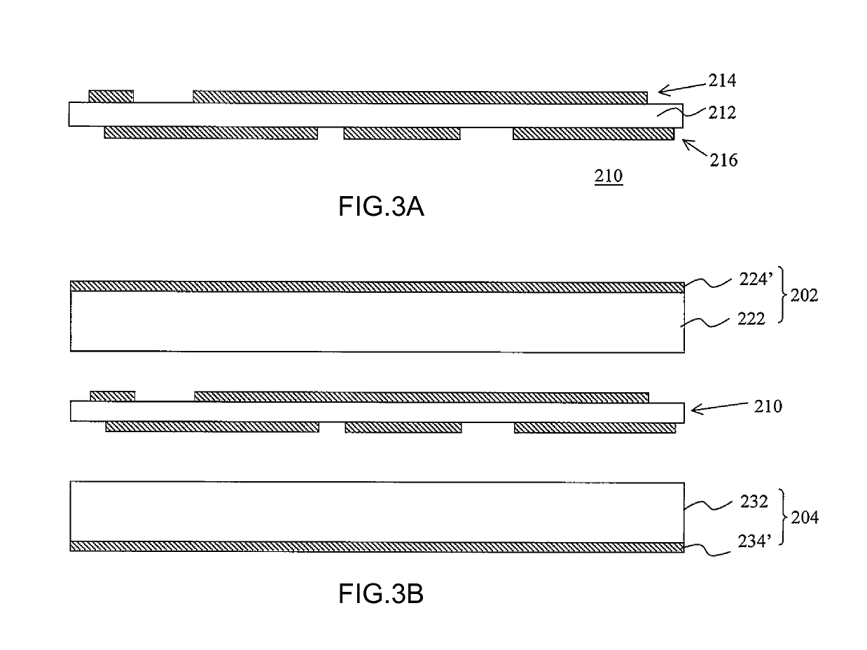

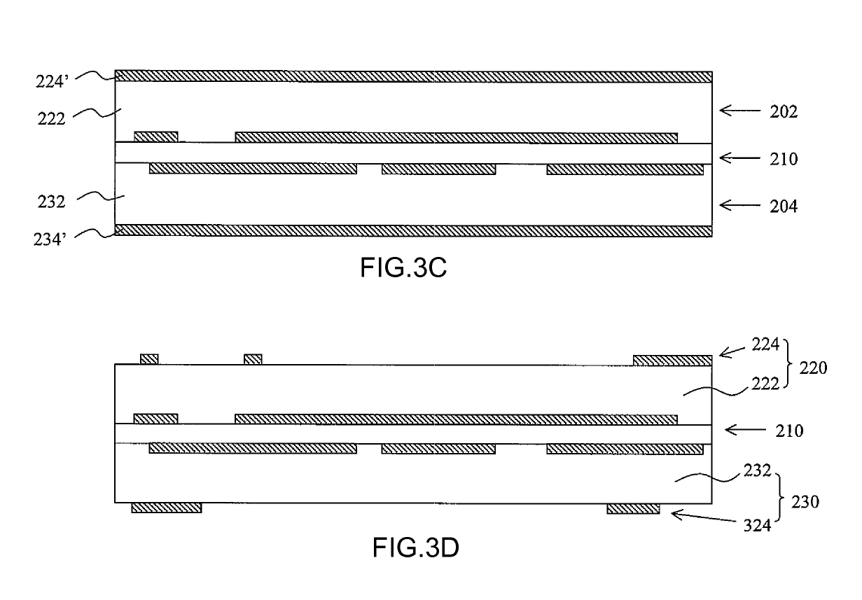

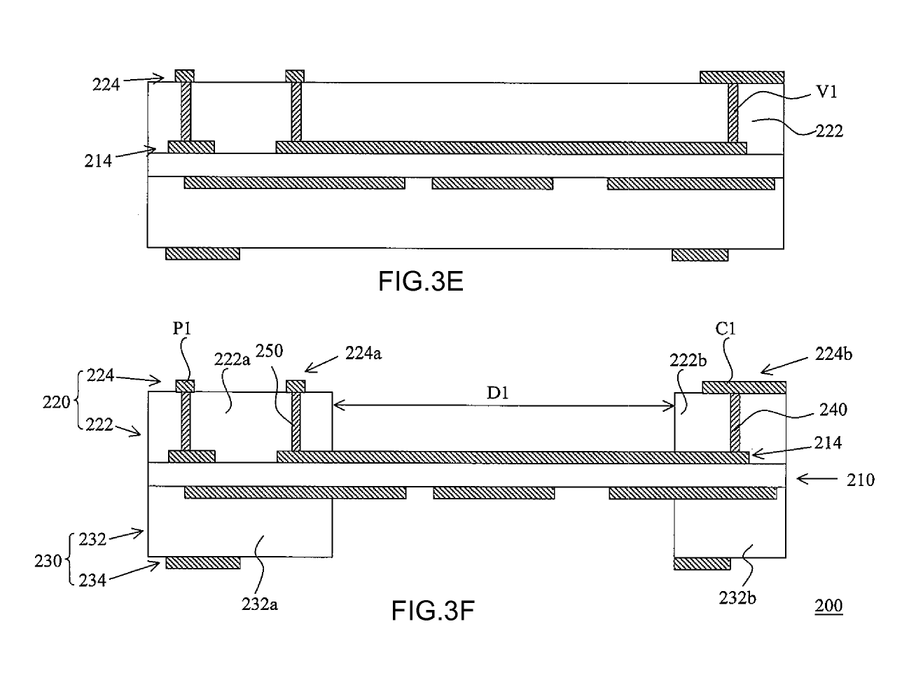

A method of manufacturing the combined circuit board 200 according to this embodiment of the present invention is described below. FIG. 3A through FIG. 3F are schematic views illustrating a method of manufacturing a combined circuit board according to an embodiment of the present invention. First, referring to FIG. 3A, a flexible circuit board 210 which comprises a flexible dielectric layer 212 and two circuit layers 214 and 216 is provided. Afterward, referring to FIG. 3B, two rigid substrates 202 and 204 are provided. The rigid substrate 202 comprises the rigid dielectric layer 222 and a conductive layer 224′ disposed on the rigid dielectric layer 222. The rigid substrate 204 comprises the rigid dielectric layer 232 and a conductive layer 234′ disposed on the rigid dielectric layer 232. Afterward, referring to FIG. 3C, the flexible circuit board 210 and the rigid substrates 202 and 204 are laminated together such that the rigid substrates 202 and 204 are disposed on the two opposite sides of the flexible circuit board 210, respectively. The rigid dielectric layer 222 is disposed between the conductive layer 224′ and the flexible circuit board 210. The rigid dielectric layer 232 is disposed between the conductive layer 234′ and the flexible circuit board 210.

Afterward, referring to FIG. 3D, the conductive layers 224′ and 234′ is patterned to form the circuit layers 224 and 234. The patterning step includes related procedures containing photoresist coating, photolithography (exposure and development), and etching. At this time, the rigid dielectric layer 222 and the circuit layer 224 together form the rigid circuit board 220, and the rigid dielectric layer 232 and the circuit layer 234 together form the rigid circuit board 230. Afterward, referring to FIG. 3E, a plurality of conductive vias V1 are formed in the rigid dielectric layer 222 by means of machinery drilling or laser drilling and electroplating. Each of the conductive vias V1 electrically connects the second circuit layer 224 and the first circuit layer 214.

Afterward, referring to FIG. 3F, a portion of the rigid circuit board 220 and a portion of the rigid circuit board 230 are removed such that a portion of the flexible circuit board 210 is exposed, i.e., a portion of each of the two opposite sides of the flexible circuit board 210 is exposed. At this time, the combined circuit board 200 of this embodiment is finished.

After the step depicted in FIG. 3F, the rigid dielectric layer 222 is divided into a rigid dielectric portion 222a and a rigid dielectric portion 222b which are spaced apart from each other by the distance D1. The circuit layer 224 is divided into the main circuit 224a disposed on the rigid dielectric portion 222a and the out connection interface circuit 224b disposed on the rigid dielectric portion 222b. The conductive vias V1 are divided into the conductive vias 240 disposed in the rigid dielectric portion 222b and the conductive vias 250 disposed in the rigid dielectric portion 222a. Each of the conductive vias 240 electrically connects one of the contacts C1 of the out connection interface circuit 224b and the circuit layer 214. Each of the conductive vias 250 electrically connects one of the pads P1 of the main circuit 224a and the circuit layer 214. Moreover, the rigid dielectric layer 232 is divided into the rigid dielectric portions 232a and 232b which are spaced apart from each other. The rigid dielectric portions 232a and 232b correspond in position to the rigid dielectric portions 222a and 222b, respectively.

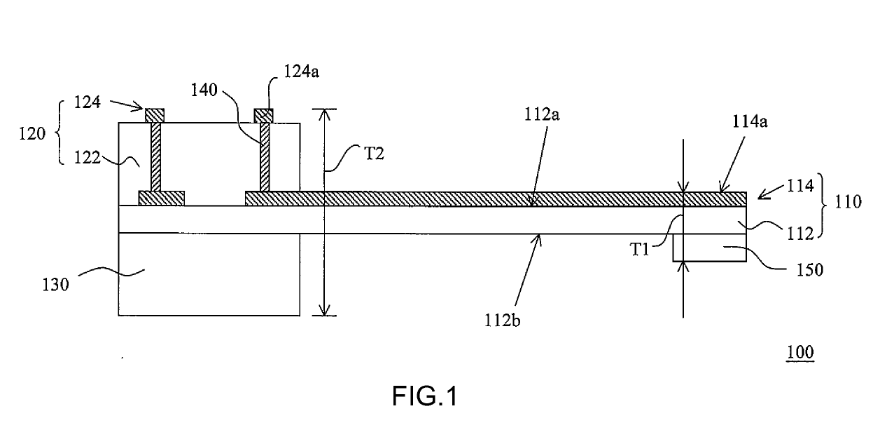

In this embodiment, the contacts C1 of the out connection interface circuit 224b of the circuit layer 224 are formed on the rigid dielectric layer 222 of the rigid circuit board 220 at the step of patterning the conductive layer 224.′ In this embodiment, the contacts C1 are not formed yet during the laminating step and are being formed during the patterning step. Hence, compared to the conventional art, the contacts C1 of the present embodiment do not require additional protection during the two steps and the reinforcing plate 150 (see FIG. 1) is not required while the contacts C1 are being formed. Accordingly, compared to the conventional art, the method of manufacturing the combined circuit board 200 of the present embodiment is relatively simple.

Based on the above mentioned, the combined circuit board has one of the following advantages or another advantage.

During the manufacturing process of the combined circuit board of the embodiment of the present invention, the contact of the rigid circuit board comprising the out connection interface circuit is formed on the rigid dielectric layer of the rigid circuit board at the step of patterning the conductive layer. In this embodiment of the present invention, the contact is not formed yet during the laminating step and is being formed during the patterning step. Hence, compared to the conventional art, the contact of the embodiment of the present invention does not require additional protection during the two steps and the reinforcing plate is not required while the contact is being formed. Accordingly, the method of manufacturing the combined circuit board of the embodiment of the present invention is relatively simple.

Because the rigid dielectric layer comprises the epoxy resin and the glass fabric which meets the style 1017 of the IPC standard, compared to the conventional art, the thickness of the rigid dielectric layer can be reduced and the structural strength requirements for the rigid dielectric layer can be still meet such that the maximum thickness of the combined circuit board of this embodiment of the present invention can be effectively reduced and therefore, the combined circuit board can be thinner.

What is claimed is:

1. A combined circuit board, comprising:
a flexible circuit board comprising a flexible dielectric layer and a first circuit layer disposed on the flexible dielectric layer;
a first rigid circuit board, comprising:
a first rigid dielectric layer disposed on the flexible circuit board and comprising a first rigid dielectric portion and a second rigid dielectric portion spaced apart from the first rigid dielectric portion by a distance to expose a portion of the flexible circuit board; and
a second circuit layer comprising a main circuit and an out connection interface circuit, the main circuit being disposed on the first rigid dielectric portion, and the out connection interface circuit being disposed on the second rigid dielectric portion and comprising at least one contact;
at least one first conductive via disposed in the second rigid dielectric portion and electrically connecting the at least one contact and the first circuit layer; and
at least one second conductive via disposed in the first rigid dielectric portion and electrically connecting the main circuit and the first circuit layer.

2. The combined circuit board of claim 1, wherein the first rigid dielectric layer comprises an epoxy resin and a glass fabric which meets the style 1017 of the IPC standard.

3. The combined circuit board of claim 1, wherein the flexible circuit board further comprises a third circuit layer disposed on the flexible dielectric layer, the first circuit layer and the third circuit layer are disposed on two opposite sides of the flexible dielectric layer, respectively, the combined circuit board further comprises a second rigid circuit board comprising a second rigid dielectric layer and a fourth circuit layer, the second rigid dielectric layer is disposed on the flexible circuit board, the fourth circuit layer is disposed on the second rigid dielectric layer, the second rigid dielectric layer comprises a third rigid dielectric portion and a fourth rigid dielectric portion, the third rigid dielectric portion and the fourth rigid dielectric portion correspond in position to the first rigid dielectric portion and the second rigid dielectric portion, respectively, and the second rigid circuit board and the first rigid circuit board are disposed on two opposite sides of the flexible circuit board, respectively.

4. The combined circuit board of claim 3, wherein the first rigid dielectric layer comprises an epoxy resin and a glass fabric which meets the style 1017 of the IPC standard, and the second rigid dielectric layer comprises an epoxy resin and a glass fabric which meets the style 1017 of the IPC standard, and the combined circuit board has a maximum thickness which is not larger than 0.2 mm.

5. The combined circuit board of claim 1, wherein the at least one contact is a golden finger contact.

6. A method of manufacturing a combined circuit board, comprising:
providing a flexible circuit board comprising a flexible dielectric layer and a first circuit layer disposed on the flexible dielectric layer;
providing a first rigid substrate comprising a first rigid dielectric layer and a first conductive layer disposed on the first rigid dielectric layer;
laminating the flexible circuit board and the first rigid substrate such that the first rigid dielectric layer is located between the first conductive layer and the flexible circuit board;
patterning the first conductive layer to form a second circuit layer, wherein the first rigid dielectric layer and the second circuit layer together form a first rigid circuit board;
forming a plurality of conductive vias in the first rigid dielectric layer, wherein each of the conductive vias electrically connects the second circuit layer and the first circuit layer;
removing a portion of the first rigid circuit board to expose a portion of the flexible circuit board, wherein the first rigid dielectric layer is divided into a first rigid dielectric portion and a second rigid dielectric portion spaced apart from the first rigid dielectric portion by a distance, the second circuit layer is divided into a main circuit and an out connection interface circuit, the conductive vias are divided into at least one first conductive via and at least one second conductive via, the main circuit is disposed on the first rigid dielectric portion, the out connection interface circuit is disposed on the second rigid dielectric portion and comprises at least one contact, the at least one first conductive via is disposed in the second rigid dielectric portion and electrically connects the at least one contact and the first circuit layer, and the at least one second conductive via is disposed in the first rigid dielectric portion and electrically connects the main circuit and the first circuit layer.

7. The method of claim 6, wherein the first rigid dielectric layer comprises an epoxy resin and a glass fabric which meets the style 1017 of the IPC standard.

8. The method of claim 6, wherein the flexible circuit board further comprises a third circuit layer disposed on the flexible dielectric layer, the first circuit layer and the third circuit layer are disposed on two opposite sides of the flexible dielectric layer, respectively, the method further comprising:
providing a second rigid substrate comprising a second rigid dielectric layer and a second conductive layer disposed on the second rigid dielectric layer;
laminating the flexible circuit board and the second rigid substrate such that the second rigid dielectric layer is located between the second conductive layer and the flexible circuit board and the second rigid substrate and the first rigid substrate are disposed on two opposite sides of the flexible circuit board, respectively;
patterning the second conductive layer to form a fourth circuit layer, wherein the second rigid dielectric layer and the fourth circuit layer together form a second rigid circuit board; and
removing a portion of the second rigid circuit board to expose another portion of the flexible circuit board, wherein the second rigid dielectric layer is divided into a third rigid dielectric portion and a fourth rigid dielectric portion, and the third rigid dielectric portion and the fourth rigid dielectric portion correspond in position to the first rigid dielectric portion and the second rigid dielectric portion, respectively.

9. The method of claim 8, wherein the first rigid dielectric layer comprises an epoxy resin and a glass fabric which meets the style 1017 of the IPC standard, and the second rigid dielectric layer comprises an epoxy resin and a glass fabric which meets the style 1017 of the IPC standard, and the combined circuit board has a maximum thickness which is not larger than 0.2 mm.

10. The method of claim 6, wherein the at least one contact is a golden finger contact.
